(19) United States
(12) Patent Application Publication
(10) Pub. No.: US 2012/0074943 A1
(43) Pub. Date: Mar. 29, 2012

(54) Apparatus and Method for Ferromagnetic Object Detector

(75) Inventors: Malcolm David MacLeod, Worcestershire (GB); Paul Daniel Baxter, Cambridge (GB); Thomas John Horton, Worcestershire (GB); Mark Nicholas Keene, Worcestershire (GB)

(73) Assignees: ADVANTAGE WEST MIDLANDS, Birmingham (UK); QINETIQ LIMITED, Hampshire (UK)

(21) Appl. No.: 13/260,393

(22) PCT Filed: Mar. 26, 2010
(86) PCT No.: PCT/GB10/00561

§ 371 Date: Dec. 7, 2011

(30) Foreign Application Priority Data
Mar. 27, 2009 (GB) 0905298.6

(51) Int. Cl. G01R 33/28; G06F 19/00; G01R 33/025

(52) U.S. Cl. 324/318; 324/225; 702/104

(57) ABSTRACT

An apparatus is provided for compensating for the effect of a moving door on a nearby ferromagnetic object detector. The ferromagnetic object detector is of a type to produce a main sensor signal indicative of the presence of a ferromagnetic object in the vicinity of the ferromagnetic object detector. Furthermore, the door is arranged relative to the ferromagnetic object detector such that movement of the door is liable to introduce an undesirable interference signal into the main sensor signal. The apparatus comprises an input (3) for receiving the main sensor signal and a door sensor signal that is responsive to an opening angle of the door. The apparatus also comprises an interference signal estimator (4) for estimating a door-related interference signal in dependence upon the door sensor signal and a model of interference for the door. The apparatus also comprises an interference signal canceller (6) for at least partially removing the estimated door-related interference signal from the main sensor signal to produce a compensated sensor signal. The apparatus also comprises an output (5) for outputting the compensated sensor signal.

The present invention relates to an apparatus and method relating to the detection of ferromagnetic objects, and in particular but not exclusively to an apparatus and method relating to the detection of ferromagnetic objects in the vicinity of magnetic resonance imaging (MRI) scanners.

Ferroguard-type sensors, such as those described in WO 2004/044620, are designed to detect ferromagnetic material passing through a “portal” (sensing region), for example at the entrance to an MRI facility, or for security purposes. The sensor sounds an alarm if there is simultaneously a person or equipment passing through the portal, and a magnetic signal is detected at the sensors.

An MRI facility typically has a large door at its entrance, and when this door is moved (to allow people to enter or leave the facility) this generates a magnetic signal. As a person or equipment passes through the portal, the simultaneous presence of this magnetic signal can cause false alarms.

False alarms are undesirable because (a) they reduce people's confidence in the sensor, causing them to be more prone to ignore its alarms when they are genuine, and (b) the door interference makes it impossible for the sensor to detect whether or not ferromagnetic items big enough to merit an alarm are in fact passing through the portal at the time.

It is desirable to provide a solution to this problem of false alarms.

According to a first aspect of the present invention there is provided an apparatus for compensating for the effect of a moving door on a nearby ferromagnetic object detector, the ferromagnetic object detector being adapted to produce a main sensor signal indicative of the presence of a ferromagnetic object in the vicinity of the ferromagnetic object detector, the door being arranged relative to the ferromagnetic object detector such that movement of the door is liable to introduce an interference signal into the main sensor signal, and the apparatus comprising: an input for receiving the main sensor signal and a door sensor signal that is responsive to an opening angle of the door; interference signal estimator means for estimating a door-related interference signal in dependence upon the door sensor signal and a model of interference for the door; interference signal canceller means for at least partially removing the estimated door-related interference signal from the main sensor signal to produce a compensated sensor signal; and an output for outputting the compensated sensor signal.

The apparatus may further comprise door angle estimator means for estimating the door angle using the door sensor signal, and wherein the interference signal estimator means are arranged to estimate the interference signal in dependence upon the estimated door angle.

The interference signal estimator means may use a model of interference for the door that comprises an element based on eddy currents caused by door shielding.

The model may be based on a dipole moving with and aligned perpendicular to the door, for example at or near the centre of the door.

The interference signal estimator means may use a model of interference for the door that that comprises an element based on remanent and/or induced magnetic effects from a handle or other metal object moving with the door.

The model may be based on a dipole moving with the door, for example at or near the handle or other metal object, in substantially fixed alignment relative to the door in the case of remanent magnetism and in substantially fixed alignment relative to a background magnetic field in the case of induced magnetism.

The received door sensor signal may comprise two signals x(t) and y(t), representing magnetic field strength in two different respective directions. The different respective directions may be substantially orthogonal directions.

The door angle estimator means may be arranged to estimate the door angle \hat{θ}(t) as a function of arctan 2(x(t), y(t)), where arctan 2 denotes a 4-quadrent arctangent function.

The interference signal estimator means may be arranged to estimate the interference signal based on at least one of the following functions:

$${I}_{eddy \_ 1} ∝ cos ( \hat{θ} ) \frac{\partial }{\partial t} ( y ( t ) ) ;$$

$${I}_{eddy \_ 2} ∝ sin ( \hat{θ} ) \frac{\partial }{\partial t} ( y ( t ) ) ;$$

$${I}_{eddy \_ 3} ∝ {cos}^{2} ( \hat{θ} ) \frac{\partial }{\partial t} ( y ( t ) ) ;$$

$${I}_{eddy \_ 4} ∝ {sin}^{2} ( \hat{θ} ) \frac{\partial }{\partial t} ( y ( t ) ) ; and$$

$${I}_{eddy \_ 5} ∝ sin ( \hat{θ} ) cos ( \hat{θ} ) \frac{\partial }{\partial t} ( y ( t ) ) ;$$

where \hat{θ}(t) represents the estimated door angle.

The interference signal estimator means may be arranged to estimate the interference signal based on at least one of the following functions:

$${I}_{remanent \_ 1} ∝ \frac{3 ( d - {x}_{1} cos ( \hat{θ} ) + {x}_{2} sin ( \hat{θ} ) ) ( r ( \hat{θ} ) \cdot u )}{{\vert r ( \hat{θ} ) \vert}^{5}} - \frac{( {u}_{1} cos ( \hat{θ} ) - {u}_{2} sin ( \hat{θ} ) )}{{\vert r ( \hat{θ} ) \vert}^{3}} ;$$

$${I}_{remanent \_ 2} ∝ \frac{3 ( - {x}_{1} sin ( \hat{θ} ) - {x}_{2} cos ( \hat{θ} ) ) ( r ( \hat{θ} ) \cdot u )}{{\vert r ( \hat{θ} ) \vert}^{5}} - \frac{( {u}_{1} sin ( \hat{θ} ) - {u}_{2} cos ( \hat{θ} ) )}{{\vert r ( \hat{θ} ) \vert}^{3}} ; and$$

$${I}_{remanent \_ 3} ∝ \frac{3 ( h - {x}_{3} ) ( r ( \hat{θ} ) \cdot u )}{{\vert r ( \hat{θ} ) \vert}^{5}} - \frac{{u}_{3}}{{\vert r ( \hat{θ} ) \vert}^{3}} ;$$

where \hat{θ} represents the door angle, where x₁,x₂,x₃ represent Cartesian coordinates of the position of a sensor of the ferromagnetic object detector relative to a hinge of the door, where r(\hat{θ}) represents a vector from the sensor to the handle or other metal object, where u represents a sensor alignment vector, where d represents a distance between the hinge of the door and the handle or other metal object, and where h represents a height difference between the sensor and the handle or other metal object. The sensor alignment vector u may comprise the Cartesian components of the pointing direction of the sensor.

The interference signal estimator means may be arranged to estimate the interference signal based on at least one of the following functions:

$${I}_{induced \_ 1} ∝ \frac{3 ( - d cos ( \hat{θ} ) - {x}_{1} ) ( r ( \hat{θ} ) \cdot u )}{{\vert r ( \hat{θ} ) \vert}^{5}} - \frac{{u}_{1}}{{\vert r ( \hat{θ} ) \vert}^{3}} ;$$

$${I}_{induced \_ 2} ∝ \frac{3 ( d sin ( \hat{θ} ) - {x}_{2} ) ( r ( \hat{θ} ) \cdot u )}{{\vert r ( \hat{θ} ) \vert}^{5}} - \frac{{u}_{2}}{{\vert r ( \hat{θ} ) \vert}^{3}} ; and$$

$${I}_{induced \_ 3} ∝ \frac{3 ( h - {x}_{3} ) ( r ( \hat{θ} ) \cdot u )}{{\vert r ( \hat{θ} ) \vert}^{5}} - \frac{{u}_{3}}{{\vert r ( \hat{θ} ) \vert}^{3}} = {I}_{remanent \_ 3} ;$$

where \hat{θ} represents the door angle, where x₁, x₂, x₃ represent Cartesian coordinates of the position of a sensor of the ferromagnetic object detector relative to a hinge of the door, where r(\hat{θ}) represents a vector from the sensor to the handle or other metal object, where u represents a sensor alignment vector, where d represents a distance between the hinge of the door and the handle or other metal object, where d represents a distance along one of the Cartesian coordinates between the hinge of the door and the handle or other metal object, and where h represents a height difference between the sensor and the handle or other metal object. The sensor alignment vector u may comprise the Cartesian components of the pointing direction of the sensor.

The door sensor may comprise two magnetic sensors, such as flux-gate sensors, arranged respectively to produce the two signals x(t) and y(t).

The flux-gate sensors may be arranged with substantially orthogonal headings.

One of the flux-gate sensors may be arranged substantially parallel to the door and to the ground, while the other is arranged substantially parallel to the ground and orthogonal to the door.

The interference signal canceller means may be arranged to use a block-based method of at least partially removing the estimated door-related interference signal from the main sensor signal, for example an adaptive cancellation method.

The interference signal canceller means may be arranged to determine the compensated sensor signal S′ according to S′=S−ρX where S is a data vector and X is a data matrix, containing the main signal and modelled interference signals respectively, and where ρ is a vector of cancellation coefficients calculated according to ρ=SX^{H}(XX^{H})⁻¹.

According to a second aspect of the present invention there is provided a system comprising a ferromagnetic object detector and an apparatus according to the first aspect of the present invention.

According to a third aspect of the present invention there is provided a magnetic resonance imaging scanner comprising a system according to the second aspect of the present invention.

According to a fourth aspect of the present invention there is provided a method for compensating for the effect of a moving door on a nearby ferromagnetic object detector, the ferromagnetic object detector being adapted to produce a main sensor signal indicative of the presence of a ferromagnetic object in the vicinity of the ferromagnetic object detector, the door being arranged relative to the ferromagnetic object detector such that movement of the door is liable to introduce an interference signal into the main sensor signal, and the method comprising: receiving the main sensor signal and a door sensor signal that is responsive to an opening angle of the door; estimating a door-related interference signal in dependence upon the door sensor signal and a model of interference for the door; at least partially removing the estimated door-related interference signal from the main sensor signal to produce a compensated sensor signal; and outputting the compensated sensor signal.

According to a fifth aspect of the present invention there is provided a program for controlling an apparatus to perform a method according to the fourth aspect of the present invention or which, when loaded into an apparatus, causes the apparatus to become an apparatus according to the second aspect of the present invention. The program may be carried on a carrier medium. The carrier medium may be a storage medium. The carrier medium may be a transmission medium.

According to a sixth aspect of the present invention there is provided an apparatus programmed by a program according to the third aspect of the present invention.

According to a seventh aspect of the present invention there is provided a storage medium containing a program according to the third aspect of the present invention.

An embodiment of the present invention aims to cancel or at least reduce the effects of door-related signals as accurately as possible, in order to reduce the number of false alarms and to restore as much as possible of the sensor's ability to detect small ferromagnetic objects genuinely passing through the detection portal.

The approach adopted according to one embodiment of the present invention involves:
1. The use of sensors (which could be magnetic) on the door itself to produce signals related to the door motion; and
2. Adaptive (learning) algorithms incorporating mathematical models of several different components of magnetic interference that are produced when the door moves (some relate to the angle of the door; others relate to the rate at which the door is swinging), in order to cancel the interference. These algorithms adjust themselves to the particular door and configuration of Ferroguard sensors, so as to make the cancellation of interference as good as possible.

Although the second feature above could be used in conjunction with a sensor of door position other than magnetic sensors, it may be that the use of magnetic sensors on the door enables more accurate modelling of some of the interference terms.

Reference will now be made, by way of example, to the accompanying drawings, in which:

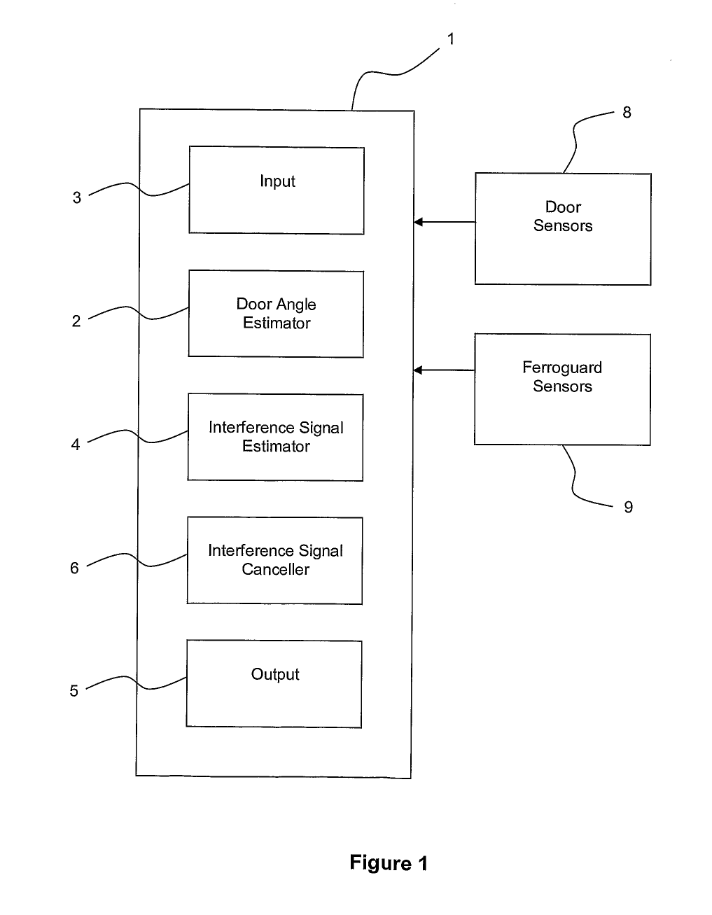

FIG. 1 is a schematic representation of an apparatus according to an embodiment of the present invention;

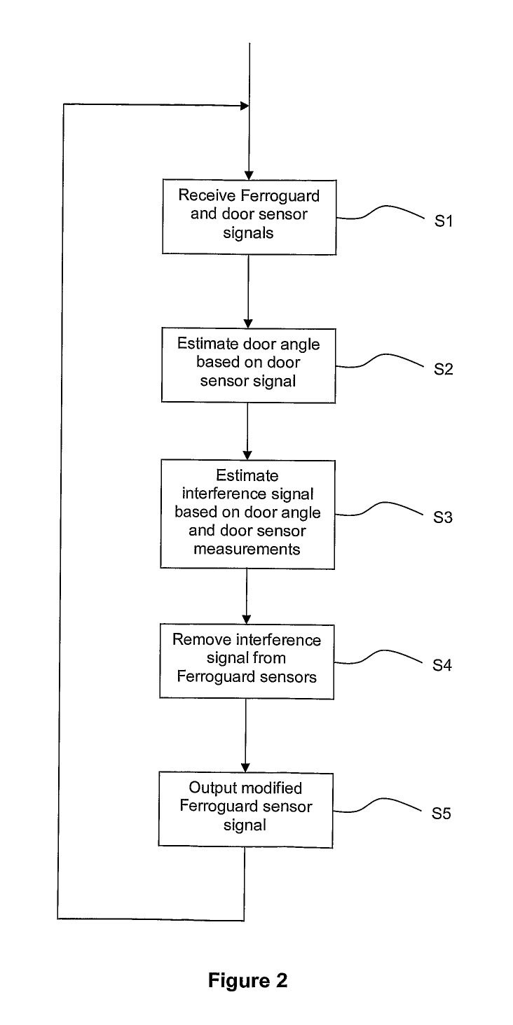

FIG. 2 is a schematic flow diagram illustrating steps performed by the apparatus of FIG. 1 in a method embodying the present invention;

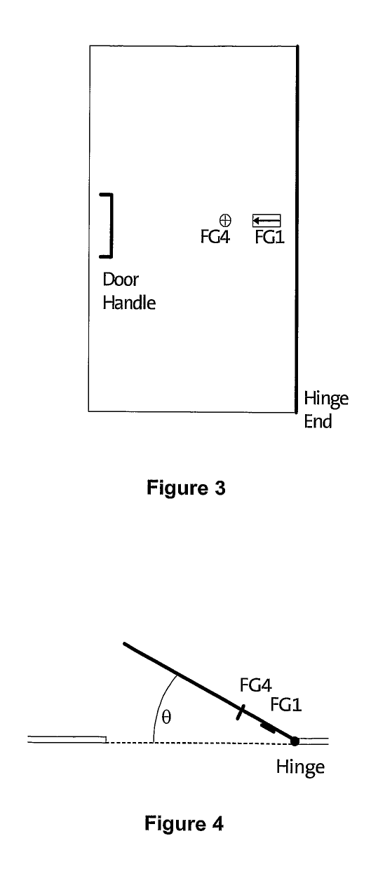

FIG. 3 is a face view illustrating the positioning of flux gates (door sensors) on a door, for use in explaining the estimation of door angle in an embodiment of the present invention;

FIG. 4 is a plan view of the door and flux gates (door sensors) of FIG. 3, for use in explaining the estimation of door angle in an embodiment of the present invention;

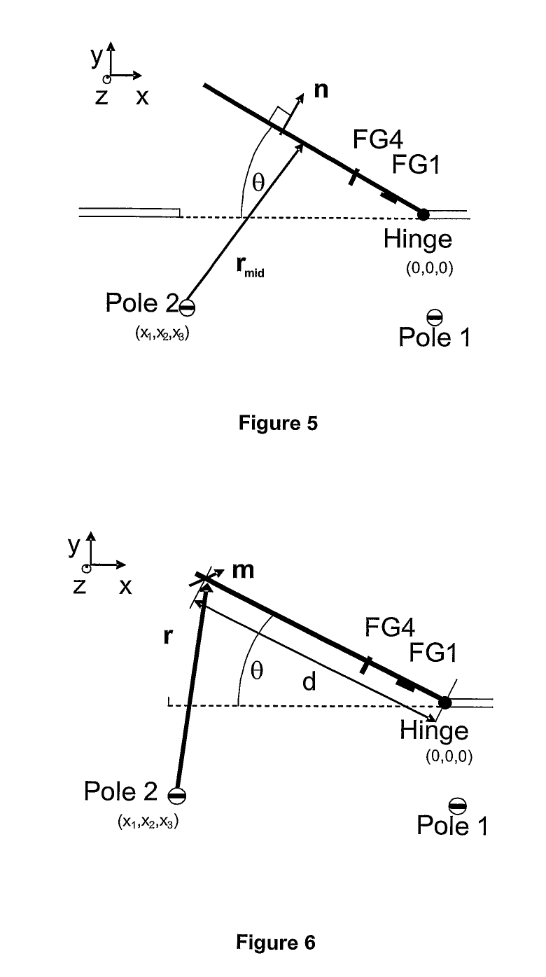

FIG. 5 is a plan view of a door and flux gates (door sensors) for use in explaining an eddy current interference signal model used in an embodiment of the present invention;

FIG. 6 is a plan view of a door and flux gates (door sensors) for use in explaining a door handle interference signal model used in an embodiment of the present invention;

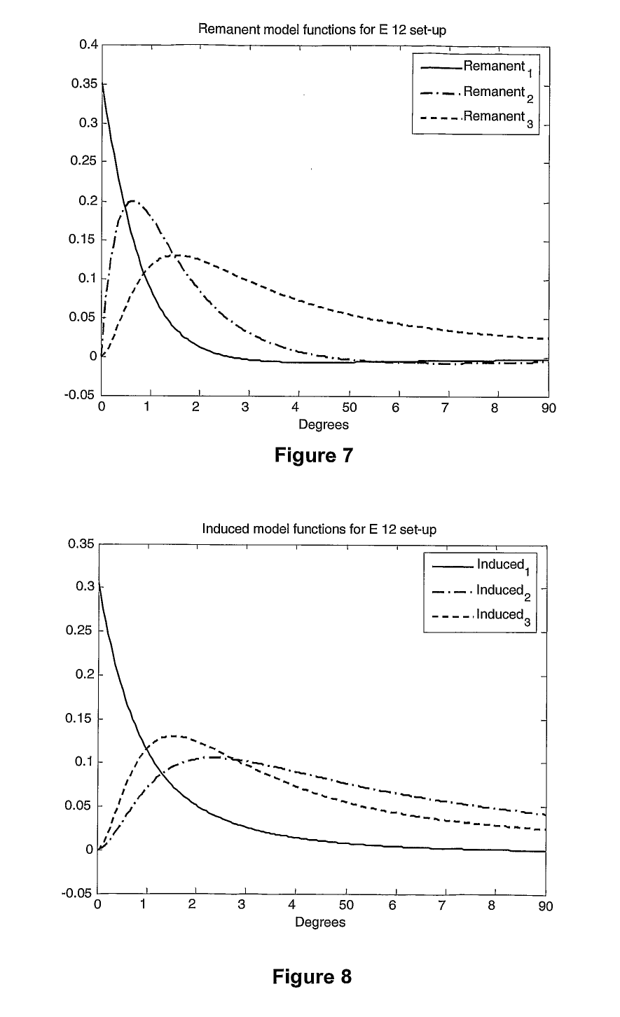

FIG. 7 illustrates remanent model functions shown as a function of angle;

FIG. 8 illustrates induced model functions shown as a function of angle;

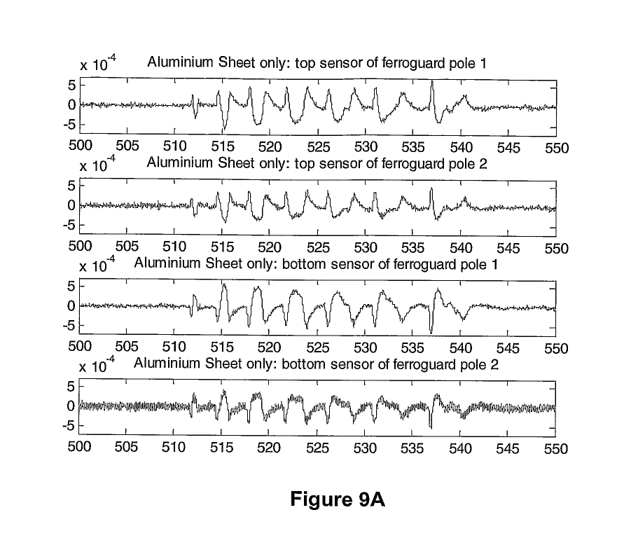

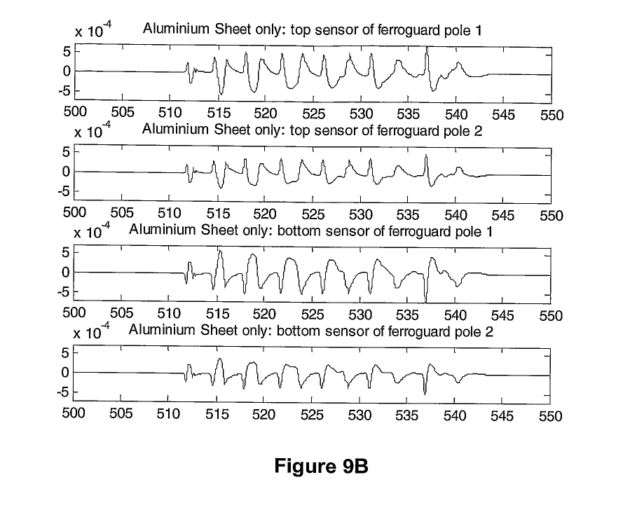

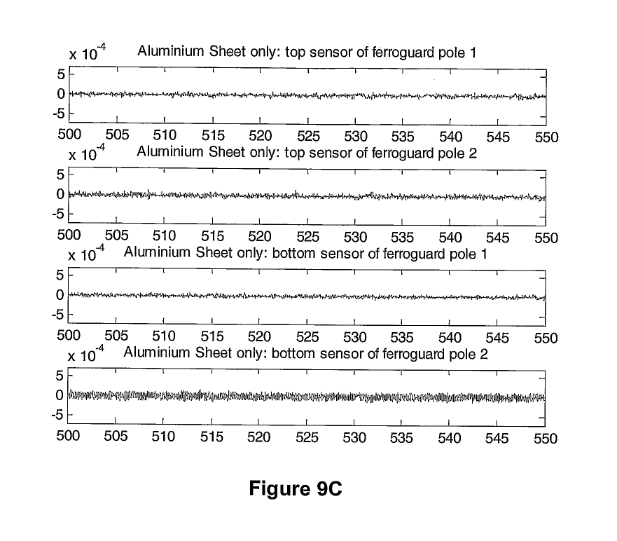

FIGS. 9A to 9C illustrate data for Ferroguard sensors during rapid door movement of a handleless door, with FIG. 9A showing filtered data, FIG. 9B showing fitted modelled interference, and FIG. 9C showing residual data;

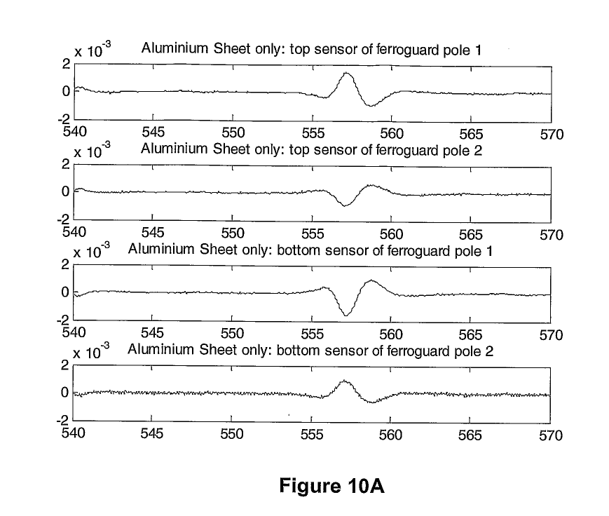

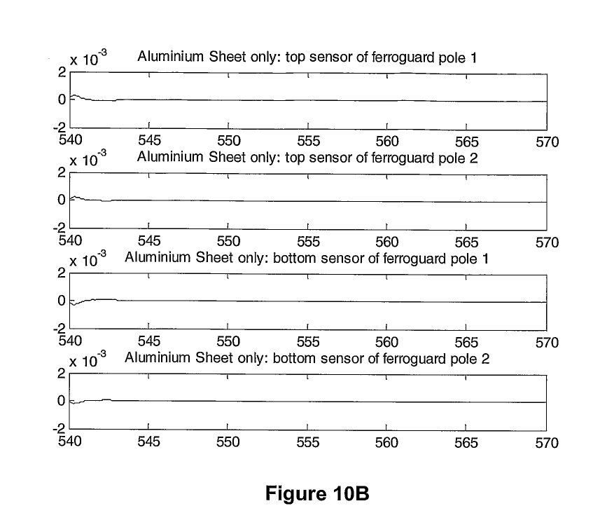

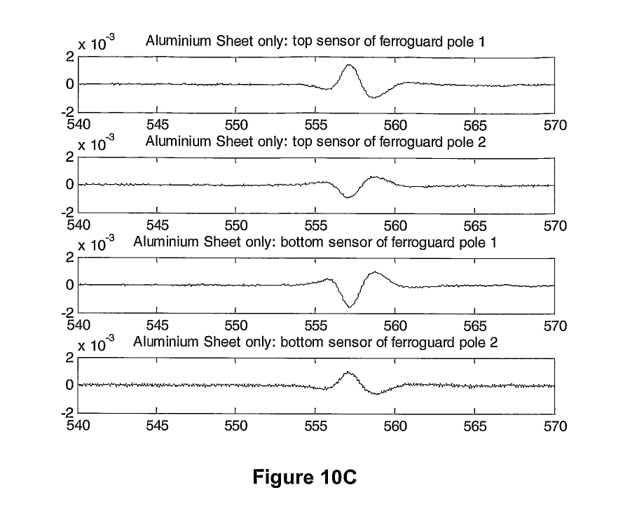

FIGS. 10A to C illustrate data for Ferroguard sensors with no door motion, but possibly a car passing by, with FIG. 10A showing filtered data, FIG. 10B showing fitted modelled interference, and FIG. 10C showing residual data;

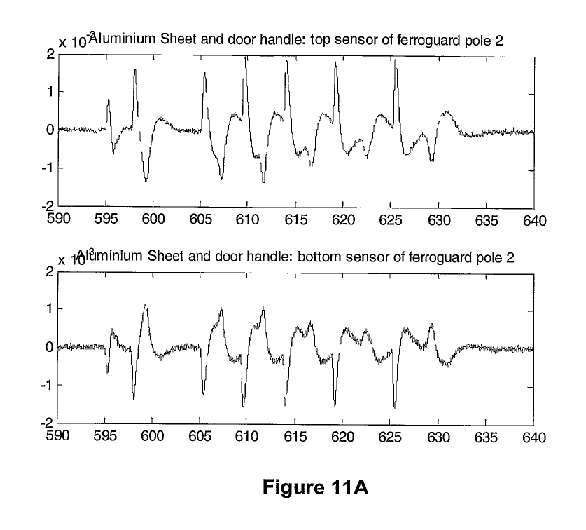

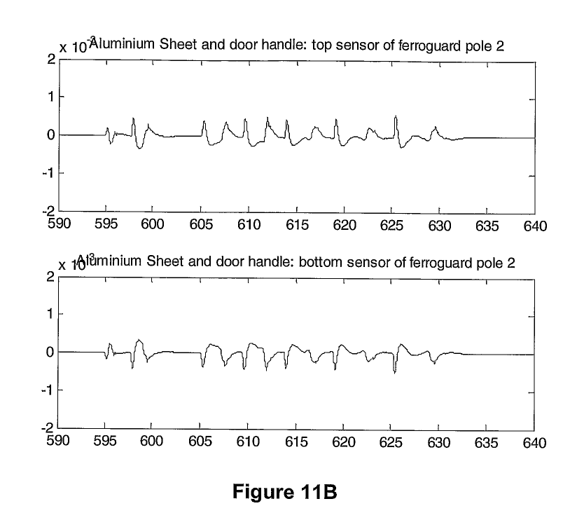

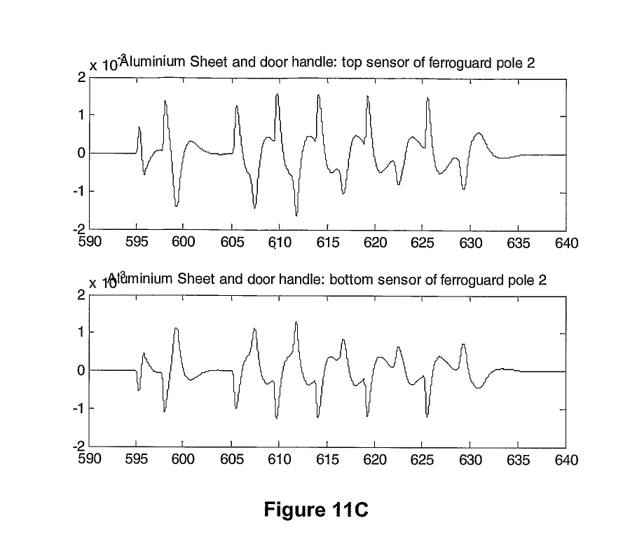

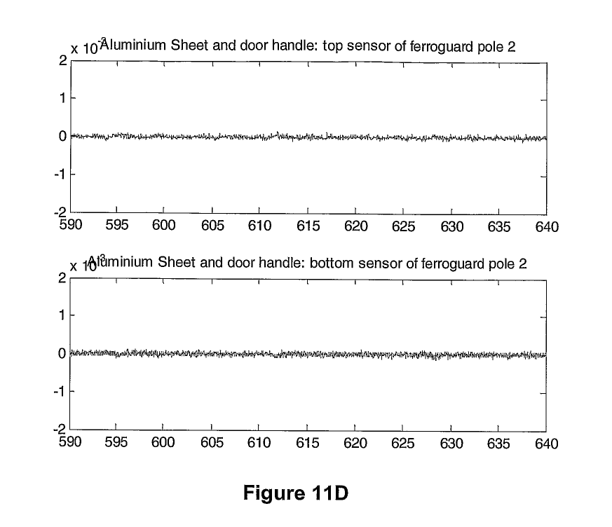

FIGS. 11A to 11D illustrate data for Ferroguard sensors during rapid door motion, with FIG. 11A showing filtered data, FIG. 11B showing fitted modelled interference for eddy currents, FIG. 11C showing fitted modelled interference for door handle effects, and FIG. 11D showing residual data;

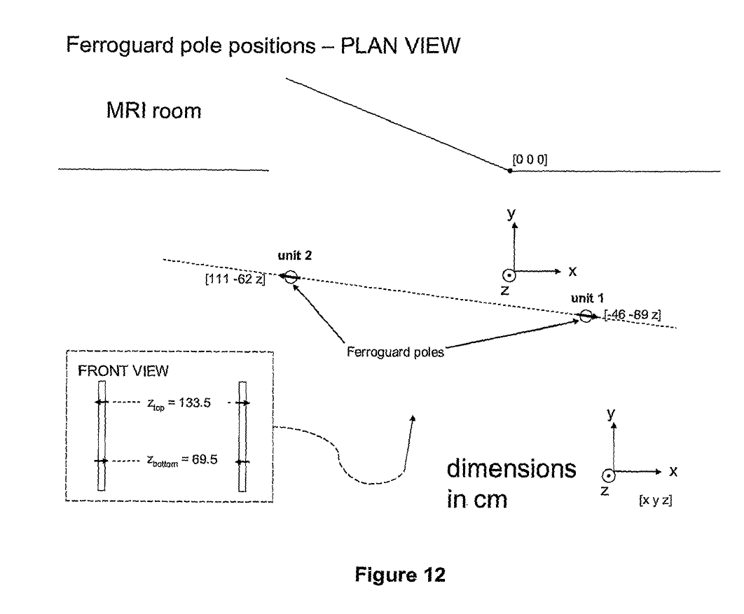

FIG. 12 is a plan view of an experimental set-up for use in demonstrating an embodiment of the present invention;

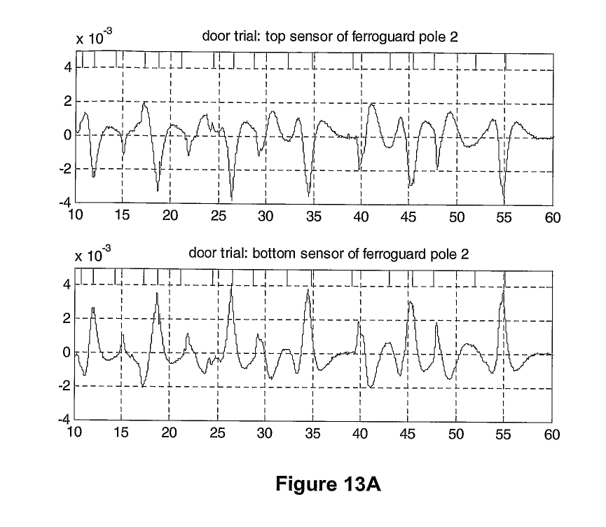

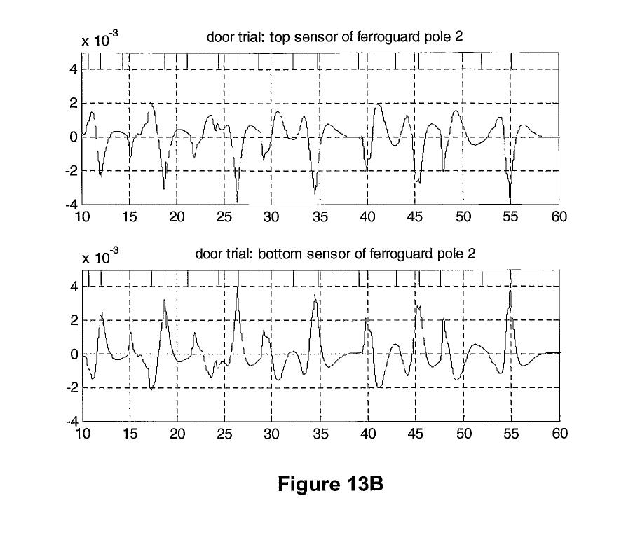

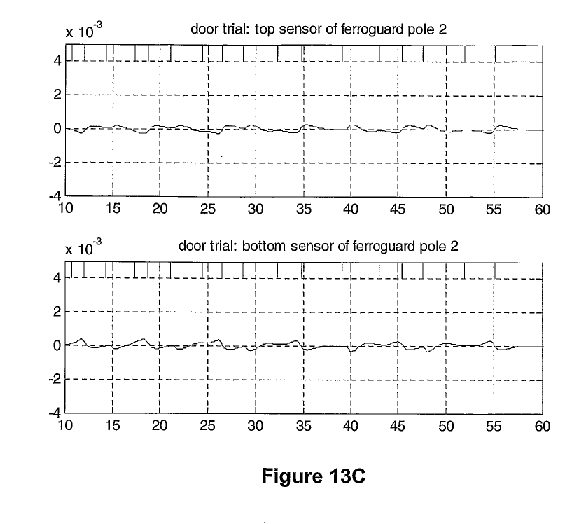

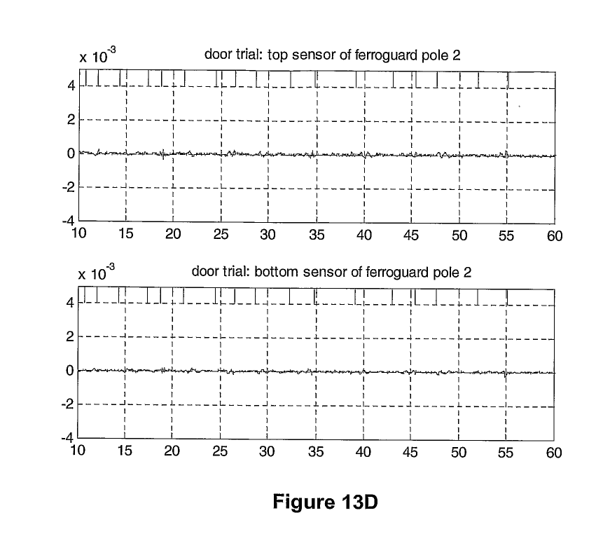

FIGS. 13A to 13D illustrate data for Ferroguard sensors during rapid door motion outside an MRI facility, with FIG. 13A showing filtered data, FIG. 13B showing fitted modelled interference for eddy currents, FIG. 13C showing fitted modelled interference for door handle effects, and FIG. 13D showing residual data; and

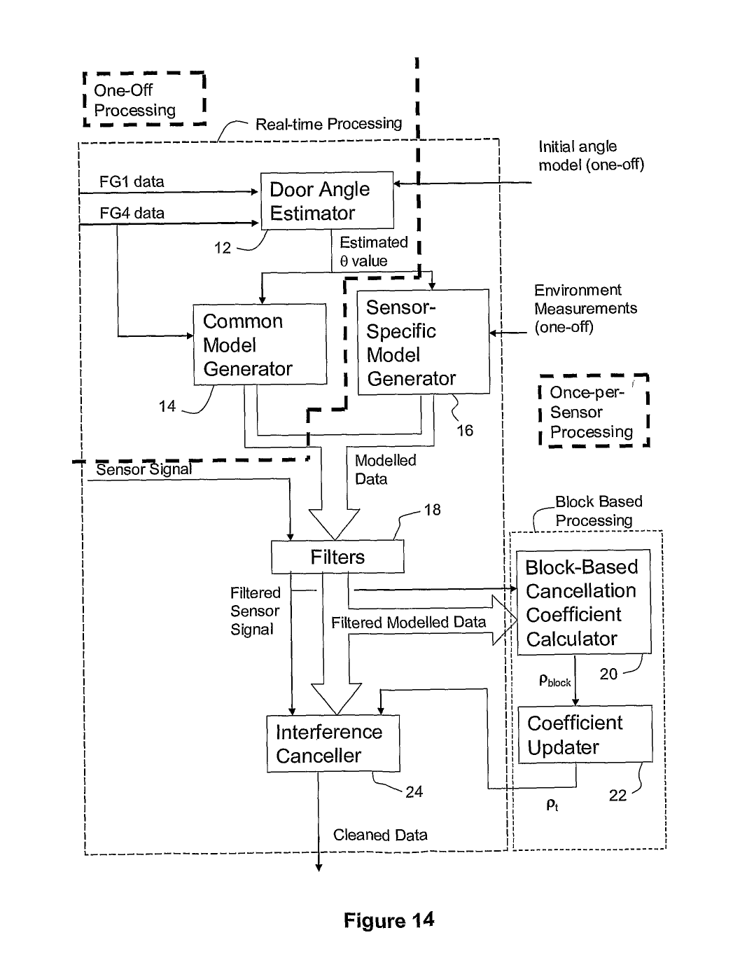

FIG. 14 is a schematic block diagram showing an example of a real-time implementation of the door motion cancellation algorithm according to an embodiment of the present invention.

In order to address the above-described problem relating to false alarms caused by a moving door in the vicinity of Ferroguard sensors, an apparatus according to an embodiment of the present invention is provided as illustrated schematically in FIG. 1. The apparatus 1 comprises five main components: an input 3; a door angle estimator 2; an interference signal estimator 4; an interference signal canceller 6; and an output 5. The input 3 is arranged to receive a signal from door sensors 8, which would typically be mounted on the door, and from the Ferroguard sensors 9. The output 5 is arranged to output a signal produced by the interference signal canceller.

The apparatus 1 aims to remove or at least reduce the effect of interfering signals caused by motion of the door, and in this respect it has been identified by the present applicant that there are two main sources of interfering signal: (a) eddy currents in the door shielding; and (b) direct magnetic effects from the door handle. This will be discussed in more detail below.

The apparatus 1 operates a method according to an embodiment of the present invention that consists of five main steps, as is illustrated schematically in FIG. 2. In step S1, the input 3 receives a signal from door sensors 8 and from the Ferroguard sensors 9. In step S2, the door angle estimator 2 uses the signal from the door sensors 8 to estimate the angle of the door. In step S3, the interference signal estimator 4 uses models to estimate the interference signal based on the door angle and door sensor measurements. In step S4, the interference signal canceller 6 removes the interference signal from the signal received from the Ferroguard sensors 9, or at least reduces the effect of the interference signal on the Ferroguard sensor signal, to produce a modified signal. Finally, in step S5 the output 5 outputs the modified signal produced by the interference signal canceller 6. Processing continues in a loop, returning to step S1.

Based on the overview provided by FIGS. 1 and 2 and associated description as presented above, an embodiment of the present invention will now be described in more detail.

Concerning the estimation of the door angle as mentioned above with reference to step S1 of FIG. 2, the method used in this embodiment of the present invention involves two flux-gate sensors mounted on the door, with orthogonal headings. One sensor is parallel to the door and to the ground, while the other is parallel to the ground and orthogonal to the door.

FIG. 3 shows the proposed alignment of the flux gates, with FG4 pointing in the direction of motion as the door opens. It is sensible to place the sensors at the same height as the handle, for reasons which will be discussed later. For the sake of simplicity, we will refer to the time-series data received from flux-gate 1 (FG1) as x(t), and the data received from flux-gate 4 (FG4) as y(t).

With reference to a uniform field (such as the earth-field) an estimate of door angle can be obtained by considering the 4-quadrent arc-tangent of the FG1 response over the FG4 response. This should give an angle with respect to the uniform field, and by subtracting the term obtained for the ‘at rest’ position, a door angle estimate can be obtained:

\hat{θ}(t)=arctan 2(x(t), y(t))−\hat{θ}ᵣₑₛₜ

In plan view, the door angle can be drawn as shown in FIG. 4.

There is an issue with estimating the angle correctly in non-uniform fields (such as the fields produced in a real MRI chamber). This issue will be discussed further below.

Concerning models for the interference signals as mentioned above with reference to step S2 of FIG. 2, three different sources of interference signal are modelled in this embodiment of the present invention. Each model is relatively simple, and quick to calculate, and relies only upon measurements from the two sensors on the door, x(t) and y(t). It will of course be appreciated that the interference signal models described herein are merely approximations, and that different models to those described herein (for example, more accurate and hence computationally intensive models) can be used instead.

The first source of interference signal is from eddy currents, and the modelling of this source will now be described with reference to FIG. 5.

Eddy currents are caused by the shielding in the door moving through the magnetic field as the door opens. The model used for the eddy currents is that they will be proportional to the change in the flux in the direction normal to the door surface. Flux-gate 4 is aligned in this direction, and so a good model for the intensity of the eddy currents is:

$$eddy ∝ \frac{\partial }{\partial t} ( y ( t ) )$$

However, this is not a full representation, as the eddy currents will be circulating in the plane of the door. This means that they are affected by the angle of the door (relative to the fixed alignment of the Ferroguard sensors).

A simplified model for the effect of the eddy currents on a sensor is to model it as a single dipole at the centre of the door, aligned perpendicular to the door, but to ignore the range attenuation as the range can be assumed to be confined to the near-field. The field produced by this model will have the following vector at the sensor:

B∝3(n·r_{mid})r_{mid}−|r_{mid}|²n

This can be calculated in terms of the unknown door angle and position of the sensor. It works out as having five terms, proportional to cos(\hat{θ}), cos²(\hat{θ}) sin(\hat{θ}), sin²(\hat{θ}) and cos(\hat{θ})sin(\hat{θ}). Thus, the suggested eddy current models are:

$${I}_{eddy \_ 1} ∝ cos ( \hat{θ} ) \frac{\partial }{\partial t} ( y ( t ) )$$

$${I}_{eddy \_ 2} ∝ sin ( \hat{θ} ) \frac{\partial }{\partial t} ( y ( t ) )$$

$${I}_{eddy \_ 3} ∝ {cos}^{2} ( \hat{θ} ) \frac{\partial }{\partial t} ( y ( t ) )$$

$${I}_{eddy \_ 4} ∝ {sin}^{2} ( \hat{θ} ) \frac{\partial }{\partial t} ( y ( t ) )$$

$${I}_{eddy \_ 5} ∝ sin ( \hat{θ} ) cos ( \hat{θ} ) \frac{\partial }{\partial t} ( y ( t ) )$$

However, as will be shown on data later, not all of these are necessary (although they are linearly independent). In particular, the fifth of these seems not to be required for any of the data sets to which the method has currently been applied; it may be that this term is not needed but analysis of further data sets from MRI chambers would be needed to determine this.

The second source of interference signal as mentioned above is from remanent handle magnetism, and the modelling of this source will now be described with reference to FIG. 6 and FIG. 7.

Remanent magnetism in the handle will lead to it behaving (to first order) like a dipole which moves with the door; thus the angle of the dipole will change with the angle of the door. As well as the angle changing, the range to the Ferroguard sensor at the handle end will change. A plan view of the set-up (FIG. 6) shows the two active vectors, m and r, which can be considered as functions of \hat{θ}.

For the (initial) sake of simplicity, it is assumed that the range and respective angle from pole 1 to the door handle does not vary with angle. This approximation is generally valid if the distance the Ferroguard poles stand out from the door is small. If necessary, the same calculations as are done for pole 2 can be done for pole 1, producing a different set of functions.

The vector from pole 2 (position vector x) to the door handle, r, generally varies a great deal with angle, as does the vector m:

$$m ( \hat{θ} ) ≡ [ \begin{matrix}{m}_{1} cos ( \hat{θ} ) + {m}_{2} sin ( \hat{θ} ) \\ - {m}_{1} sin ( \hat{θ} ) + {m}_{2} cos ( \hat{θ} ) \\ {m}_{3}\end{matrix} ]$$

$$r ( \hat{θ} ) ≡ [ \begin{matrix}- d cos ( \hat{θ} ) - {x}_{1} \\ d sin ( \hat{θ} ) - {x}_{2} \\ h - {x}_{3}\end{matrix} ]$$

where h is the height difference between the sensor in the Ferroguard pole and the handle. As there are two sensors in the pole, this will be different for each of them; however it seems to be sufficient to take one value for this (assuming the handle is mid-way between the sensor heights).

Thus the field at sensor 2, due to the remanent magnetism of the handle will be:

$${B}_{Remanent} ∝ \frac{3 ( m ( \hat{θ} ) \cdot r ( \hat{θ} ) ) r ( \hat{θ} ) - m ( \hat{θ} ) {\vert r ( \hat{θ} ) \vert}^{2}}{{\vert r ( \hat{θ} ) \vert}^{5}}$$

Now it is assumed that the Ferroguard flux-gate sensor measures the field with direction vector u. The three unknowns are the values m₁,m₂, and m₃, corresponding to the angle of the dipole in the door. It is possible to express the interference signal as an sum of three functions with unknown weightings:

$${I}_{remanent \_ 1} ∝ \frac{3 ( d - {x}_{1} cos ( \hat{θ} ) + {x}_{2} sin ( \hat{θ} ) ) ( r ( \hat{θ} ) \cdot u )}{{\vert r ( \hat{θ} ) \vert}^{5}} - \frac{( {u}_{1} cos ( \hat{θ} ) - {u}_{2} sin ( \hat{θ} ) )}{{\vert r ( \hat{θ} ) \vert}^{3}}$$

$${I}_{remanent \_ 2} ∝ \frac{3 ( - {x}_{1} sin ( \hat{θ} ) - {x}_{2} cos ( \hat{θ} ) ) ( r ( \hat{θ} ) \cdot u )}{{\vert r ( \hat{θ} ) \vert}^{5}} - \frac{( {u}_{1} sin ( \hat{θ} ) - {u}_{2} cos ( \hat{θ} ) )}{{\vert r ( \hat{θ} ) \vert}^{3}}$$

$${I}_{remanent \_ 3} ∝ \frac{3 ( h - {x}_{3} ) ( r ( \hat{θ} ) \cdot u )}{{\vert r ( \hat{θ} ) \vert}^{5}} - \frac{{u}_{3}}{{\vert r ( \hat{θ} ) \vert}^{3}}$$

The suggested way to calculate these given the vectors u and x, and scalars h and d, would be to calculate (r(\hat{θ})·u), |r(\hat{θ})|⁻⁵ and |r(\hat{θ})|⁻³ first, and then calculate the final functions.

An example of this set of functions for differing q values is shown in FIG. 7, where u=(1,0,0), d=125 cm, x=(−125,−36,130)cm, and h=100 cm.

The third source of interference signal as mentioned above is from induced handle magnetism, and the modelling of this source will now be described with reference to FIG. 8.

Induced magnetism in the door handle is similar to the remanent magnetism, except that the dipole alignment (m) does not change with the door angle; it is permanently aligned with the background field. This leads to the following vector equations applying to the same diagram as in the previous section:

$$m ≡ [ \begin{matrix}{m}_{1} \\ {m}_{2} \\ {m}_{3}\end{matrix} ]$$

$$r ( \hat{θ} ) ≡ [ \begin{matrix}- d cos ( \hat{θ} ) - {x}_{1} \\ d sin ( \hat{θ} ) - {x}_{2} \\ h - {x}_{3}\end{matrix} ]$$

Now m is not a function of \hat{θ}. Using the same dipole model as in the previous section, a Ferroguard flux-gate aligned with direction vector u will pick up interference signals that are the sum of three functions. These functions are:

$${I}_{induced \_ 1} ∝ \frac{3 ( - d cos ( \hat{θ} ) - {x}_{1} ) ( r ( \hat{θ} ) \cdot u )}{{\vert r ( \hat{θ} ) \vert}^{5}} - \frac{{u}_{1}}{{\vert r ( \hat{θ} ) \vert}^{3}}$$

$${I}_{induced \_ 2} ∝ \frac{3 ( d sin ( \hat{θ} ) - {x}_{2} ) ( r ( \hat{θ} ) \cdot u )}{{\vert r ( \hat{θ} ) \vert}^{5}} - \frac{{u}_{2}}{{\vert r ( \hat{θ} ) \vert}^{3}}$$

$${I}_{induced \_ 3} ∝ \frac{3 ( h - {x}_{3} ) ( r ( \hat{θ} ) \cdot u )}{{\vert r ( \hat{θ} ) \vert}^{5}} - \frac{{u}_{3}}{{\vert r ( \hat{θ} ) \vert}^{3}} = {I}_{remanent \_ 3}$$

These models are plotted in FIG. 8, showing marked similarities to the remanent magnetism models (to be expected as the r⁻³ terms dominate large parts of the functions). However, significant differences can be seen, especially in the peak location in the second function.

Referring now in more detail to step S3 of FIG. 2 as mentioned above, a simple, block-based method of removing the interfering signal from another signal is adaptive cancellation. Algebraically the 1*T data vector S and the n*T data matrix X contain the signal and modelled interfering signals respectively. Then the cleaned signal S′ is calculated by:

S′=S−ρX

where the 1*n vector of cancellation coefficients, ρ, is calculated by:

ρ=SX^{H}(XX^{H})⁻¹.

This means that S′ now has zero correlation with X, according to:

$$\begin{matrix}{S}^{′} {X}^{H} = ( S - ρ X ) {X}^{H} \\ = {SX}^{H} - \frac{{SX}^{H}}{{XX}^{H}} {XX}^{H} \\ = {SX}^{H} - {SX}^{H} \\ = 0\end{matrix}$$

This is a block-based method for removing the modelled interfering signals from the data vector. However it can be used to give an indication of the performance of various real-time methods. Several real-time methods aim to apply the same processing as the block-based method, including:
LMS (slow convergence, but very stable)
RLS (fast convergence, but with some stability issues)
Block-based method for finding ρ, and real-time processing to find S′ using the ρ value from the last block

This latter methodology is the one that would typically be used, provided that the vector of interference cancellation coefficients is not significantly time-varying.

When using this processing in a real system it is important to take into account the effects of filtering. Often (as in the processing of the data sets described below) it is necessary to apply significant filters to the data to remove, e.g. high frequency noise, and to enable the signals of interest to be seen. This can be taken into account in the cancellation processing in two ways:
The modelled interference signals are passed through the same filter(s) as the data
The rise-time of the filters is ignored in calculating ρ, because the larger values produced before the filter is stable tend to incorrectly dominate the processing

Application of the above processing techniques to various data sets collected in a laboratory setting will now be described (a “real” setting will also be considered below). In this set-up, a realistically sized door was constructed, and two Ferroguard poles were placed 36 cm from one side of it. Other flux-gate sensors were placed around the door, on the door and in the nearby environment, to enable other processing questions to be answered. In this discussion only the Ferroguard flux-gates and the two door-mounted flux-gates (FG1 and FG4) will be considered. The set-up is shown in plan view in FIG. 6.

Several different experiments were performed using this set-up, and the following two data sets will be considered in order:
Data set 1: door motion without the door handle present, but with a 3 mm aluminium sheet attached to the door (representing magnetic shielding in a hospital set-up)
Data set 2: door motion with both the door handle and the aluminium sheet present

Referring first to data set 1 mentioned above, with no handle attached to the door the only expected sources of interference signal with door motion are the eddy currents. Thus, initially, this data was processed using only the I_{eddy}_{_{—}}₁ to I_{eddy}_{_{—}}₄ modelled interference terms.

The data set consisted of about 10 minutes, with a 5 sets of door motions. In each set the door was opened and closed to a set of increasing angles. The difference between the sets was the speed of door motion. The eddy currents did produce interference, and the interference was at its largest when the door motion was at its fastest. The results were produced using the whole data set, but for the purpose of clear displays only the fastest door motion section is shown in FIGS. 9A to 9C.

FIGS. 9A to 9C show that the model fit to the data is very good, with very little residual signal left after the fitted interference signal has been removed. The cancellation coefficients calculated by the algorithm (taking into account normalisation of the modelled interference) were as set out in the table below:

| Location of | | | | | |
|---|---|---|---|---|---|
| Ferroguard Sensor | | I_{eddy}_{_{—}}₁ | I_{eddy}_{_{—}}₂ | I_{eddy}_{_{—}}₂ | I_{eddy}_{_{—}}₄ |
| Pole 1 | Top | −0.8 | −2.1 | 3.3 | 3.4 |
| | Bottom | −0.8 | 2.4 | −1.8 | −3.2 |
| Pole 2 | Top | 5.1 | −4.4 | −2.9 | 3.1 |
| | Bottom | 3.8 | 4.2 | 1.6 | −3.3 |

The table below shows the (data estimated) powers in sections of the data with no door movement and in sections of the data with door movement. From these an estimate of the reduction in power of the interfering signals is calculated. This suggests a very good level of 25-30 dB reduction has been achieved. In the bottom sensors a SNR value cannot be calculated as the remaining interference signal is below the noise threshold.

| | | | | Estimated | |
|---|---|---|---|---|---|
| | | | | power | |
| | | Estimated | Estimated | in section | Estimated |
| | | power in | power in | with door | Interference |
| Location of | | section with | section with | movement | power |
| Ferroguard | | no door | door | after | reduction |
| Sensor | | movement | movement | filtering | (dB) |
| Pole 1 | Top | 0.009 | 0.793 | 0.011 | 27 |
| | Bottom | 0.009 | 0.822 | 0.010 | Infinite |
| Pole 2 | Top | 0.016 | 0.391 | 0.015 | 30 |
| | Bottom | 0.049 | 0.400 | 0.048 | Infinite |

Finally, FIGS. 10A to 10C show a different section of the data where a magnetic anomaly not caused by eddy currents is present (probably a car passing by in the road outside the laboratory). This is left unchanged by the interference removal—demonstrating that this technique does not cancel more than it is meant to.

Referring now to data set 2 mentioned above, this data set was created in a similar way to the last set, only with the door handle attached. Again, the processing will be done using the whole of the data set, but for the sake of clarity, graphs will be shown using only the most rapid door motion section. Also, only the sensors on pole 2 will be considered because pole 1 shows no door handle effects due to being located near the hinge.

First the data was processed using the eddy current terms, and the simple terms from the remanent and induced magnetism of the door handle, that is: I_{eddy}_{_{—}}₁, I_{eddy}_{_{—}}₂, I_{induced}_{_{—}}₃^{simple}, Iᵣₑₘₐₙₑₙₜ_{_{—}}₁^{simple} and Iᵣₑₘₐₙₑₙₜ_{_{—}}₃^{simple}. The results obtained are shown in FIGS. 11A to 11D.

This shows that good cancellation is achieved. The difference in scale of the eddy current effects and the door motion effects is also obvious, with the door motion effects being about 5 times larger. However, when this is used in an MRI suite, the background field is likely to be 10 times stronger, and hence the eddy currents and induced magnetism will be more significant.

The cancellation coefficients calculated by the algorithm (taking into account normalisation of the modelled interference) were:

| Sensor | I_{eddy}_{_{—}}₁ | I_{eddy}_{_{—}}₂ | I_{eddy}_{_{—}}₃ | I_{eddy}_{_{—}}₄ | Iᵣₑₘₐₙₑₙₜ_{_{—}}₁ | Iᵣₑₘₐₙₑₙₜ_{_{—}}₂ | Iᵣₑₘₐₙₑₙₜ_{_{—}}₃ | I_{induced}_{_{—}}₁ | I_{induced}_{_{—}}₂ |
|---|---|---|---|---|---|---|---|---|---|
| Top | 0.12 | −0.07 | −0.06 | 0.03 | 0.34 | −0.03 | 0.04 | −0.14 | 0.00 |
| Bottom | −0.11 | 0.06 | 0.05 | −0.03 | −1.10 | 0.02 | −0.18 | 0.82 | 0.00 |

The allocation of large coefficients into Iᵣₑₘₐₙₑₙₜ_{_{—}}₁ and I_{induced}_{_{—}}₁ suggest that both induced and remanent effects apply.

The table below shows the (data estimated) powers in sections of the data with no door movement and in sections of the data with door movement. From these an estimate of the reduction in power of the interfering signals is calculated. This suggests a very good level of 22 dB reduction has been achieved.

| | Estimated | Estimated | Estimated | Estimated |
|---|---|---|---|---|
| | power in | power in | power in | Interference |
| | section with | section with | section with | power |
| | no door | door | door | reduction |
| Sensor | movement | movement | movement | (dB) |
| Top | 0.013 | 5.677 | 0.017 | 31 |
| Bottom | 0.025 | 3.550 | 0.025 | Infinite |

To confirm that the induced and remanent effects must both be compensated for, two further trials were carried out, one with just the eddy and simple remanent terms and another using just the eddy and simple induced terms. The results are shown in the table below:

| | Estimated | | | |
|---|---|---|---|---|
| | power | Estimated | Estimated | Estimated |
| | in section | power in | power in | Interference |
| | with | section with | section with | power |
| | no door | door | door | reduction |
| Sensor | movement | movement | movement | (dB) |
| Top | 0.013 | 5.677 | 0.017 | 31 |
| Eddy + Remanent | | | | |
| Bottom | 0.025 | 3.550 | 0.025 | Infinite |
| Eddy + Remanent | | | | |
| Top | 0.013 | 5.677 | 0.029 | 25 |
| Eddy + Induced | | | | |
| Bottom | 0.025 | 3.550 | 0.035 | 25 |
| Eddy + Remanent | | | | |

This suggests that only the remanent and eddy interference effects are being seen in this data set, with the induced effects being negligible. Note that including the induced effects doesn't significantly change the outputs, but does change the ρ values a lot—because Iᵣₑₘₐₙₑₙₜ_{_{—}}₁≈I_{induced}_{_{—}}₁ for this set-up. This means that the model dependent matrix (XX^{H})⁻¹ is ill-conditioned (condition number 5*10⁷).

The processing techniques according to an embodiment of the present invention as described above will now be applied to various data sets collected in a “real” setting, that is to door-motion data sets collected at a working hospital in the presence of a real MRI magnet. This means that both the door and the magnetic fields are more complex than those achieved in the laboratory.

A plan view of the set-up is shown in FIG. 12. Not shown on the diagram of FIG. 12 are the radius of the door (120 cm from hinge to handle) and the height of the handle (100 cm).

It is not as simple to estimate the door angle in this situation as it was in the laboratory. This is because the two door-mounted flux-gates (FG1 and FG4) are not moving through a homogeneous field. Instead, the field lines will be curved in a way that depends on the relative location of the MRI magnets and the door. This will probably vary from location to location.

The change in the field as the door mounted sensors cuts through it is not too great (at least in this data). This enables a simple method of producing an accurate door angle estimator to be produced. The method uses a (one-off) set of calibration results, with the door opened to 7 different positions. The same measure for an initial angle estimate is calculated using the 4-quadrent arctangent function (denoted by “arctan 2”):

\hat{θ}_{basic}(t)=arctan 2(x(t), y(t))

This is calculated for each of the 8 door positions (including closed), using a short (2 second) averaging process to remove statistical noise. Thus a set of 8 paired measurements are produced (\hat{θ}_{basic}, φ) where φ is the correct, measured door angle and \hat{θ}_{basic} is estimated from FG1 and FG4. These 8 pairs can then be used to create a cubic spline interpolating function:

\hat{θ}(t)=F(\hat{θ}_{basic}(t))=F(arctan 2(x(t), y(t)))

As this would have to be carried out as part of the installation procedure, it would even be useful to test how valid the model is when a simple installation procedure is used to create the model.

Using the same filtering and data processing, interference signals from the fast door movement set of data were cancelled. The results are shown in FIGS. 13A to 13D. These show the marked increase in the eddy effects, and hence most of the modelling has to account for these rather than for the dipole effects. However the dipole effects are still significant, and could not be left out.

It is very hard to devise a simple measure of performance, as there is not a ‘quiet’ non-signal section of the data to enable a reduction in interference level to be calculated. However the results, as shown in FIGS. 13A to 13D, are very promising, with almost no interference signal breakthrough onto a low level of background noise. The only slight interfering signals remaining seem to be at times of rapid change in door speed (doors opening, reaching largest angle and closing, as marked by short vertical lines in the upper-most sections of the various graphs).

The signal powers before the processing are 10.58 and 11.64 for the top and bottom sensors. After the processing these have been reduced to 0.030 and 0.026 respectively, which is a very significant reduction.

The cancelling coefficients used are shown in the table below. These suggest that all three types of interfering signal are present, with the eddy currents dominating.

| Sensor | I_{eddy}_{_{—}}₁ | I_{eddy}_{_{—}}₂ | I_{eddy}_{_{—}}₃ | I_{eddy}_{_{—}}₄ | Iᵣₑₘₐₙₑₙₜ_{_{—}}₁ | Iᵣₑₘₐₙₑₙₜ_{_{—}}₂ | Iᵣₑₘₐₙₑₙₜ_{_{—}}₃ | I_{induced}_{_{—}}₁ | I_{induced}_{_{—}}₂ |
|---|---|---|---|---|---|---|---|---|---|
| Top | 0.10 | −0.25 | 0.09 | 0.18 | −1.87 | −0.26 | −1.58 | 0.25 | 0.30 |
| Bottom | −0.10 | 0.24 | −0.09 | −0.17 | −1.09 | −0.29 | −0.84 | 0.25 | 0.30 |

However, if the same processing is carried out without the remanent, or without the induced, models, the results are indistinguishable from the all-models results. This suggests that in this set-up (where the Ferroguard poles are over half a meter way from the door when it's closed) the remanent and induced models are very similar.

Further detail will now be provided with regard to the implementation of the proposed algorithms. Implementation will require some real-time processing. However, in a similar manner to the interfering signal canceller, the weight calculator can be run in a block mode, while the signal canceller must run in real-time.

The suggested approach to real-time door motion cancellation consists of the following processing blocks, as illustrated for a single Ferroguard sensor in FIG. 14:
Door Angle Estimator 12: this runs in real time, takes the FG1 and FG4 sensor outputs as its inputs and returns a real-time door angle estimate;
Common Model Generator 14: this runs in real time, takes a door angle estimate and the corresponding FG4 value as its real time inputs and returns 4 model values for each sensor in real time;
Sensor Specific Model Generator 16: this runs in real time, takes a door angle estimate as its real time input, requires measurements of the sensor location, orientation and door size, and returns 5 model values for each sensor in real time;
Filter (or Filters) 18: the high pass and low pass filters designed to remove high frequency noise, out-of-band signals and DC drift;
Coefficient Calculator 20: this looks at a block of data from the Ferroguard sensor and the corresponding model data, and calculates the cancellation coefficient for this block;
Coefficient Updater 22: this carries a current estimate of the correlation coefficients ρ, and when it receives new values of these, it updates them according to some method;
Interference Canceller 24: this operates in real time on individual time samples of data from the Ferroguard sensor and the corresponding model data, and applies the cancellation by subtracting ρ times the model data from the sensors.

Generally, block 12 can be considered to correspond to block 2 of FIG. 1, blocks 14 and 16 can collectively be considered to correspond to block 4 of FIG. 1, and blocks 18, 20, 22 and 24 can collectively be considered to correspond to block 6 of FIG. 1 (block 18 consists of a bank of filters, one of them processing each sensor signal, and the others—having matching characteristics as mentioned on page 14—used to process the computed signals which are used in interference calculation; therefore, part of block 18 can be considered to relate to a separate “filtering” block in FIG. 1, not shown).

Each of the above blocks will now be described in turn.

The Door Angle Estimator 12 requires the setting up of a cubic spline model in one embodiment. Once this model is obtained, all this block has to do is take in FG1 and FG4 time samples and calculate (according to section 3.1) the value of \hat{θ}(t). This could be done via direct calculation, or via a stratified look-up table. This latter option would reduce the accuracy of the estimates, but might also reduce computational costs. However, this block is unlikely to be the heaviest used of computational resources, so the former option is to be preferred.

The Door Angle Estimator 12 has the following as inputs:
Cubic Spline Coefficients (four) (one off)
FG1 data (Flux gate aligned parallel to door)—one real sample per sample time
FG4 data (Flux gate aligned perpendicular to door)—one real sample per sample time

The Door Angle Estimator 12 has the following as outputs:
Estimated θ value—one real sample per sample time

The Common Model Generator 14 takes in the door angle estimate for each time sample and the corresponding FG4 value, and calculates the values of four(five) data models. These models apply to all the different sensors.

The suggested processing for the Common Model Generator 14 is:
Background: calculate cos(\hat{θ}) and sin(\hat{θ})
Eddy model: calculate

$$\frac{\partial }{\partial t} ( y ( t ) ) , then {I}_{eddy \_ 1} = cos ( \hat{θ} ) \frac{\partial }{\partial t} ( y ( t ) ) , \\ {I}_{eddy \_ 2} = sin ( \hat{θ} ) \frac{\partial }{\partial t} ( y ( t ) ) , \\ {I}_{eddy \_ 3} = {cos}^{2} ( \hat{θ} ) \frac{\partial }{\partial t} ( y ( t ) ) and$$

$${I}_{eddy \_ 4} = {sin}^{2} ( \hat{θ} ) \frac{\partial }{\partial t} ( y ( t ) )$$

The Common Model Generator 14 has the following as inputs:
Estimated θ value—one real sample per sample time, from Door Angle Estimator
FG4 data (Flux gate aligned perpendicular to door)—one real sample per sample time

The Common Model Generator 14 has the following as output:
Modelled Data—four (or five) real samples per sample time

The Sensor-Specific Model Generator 16 uses the door angle estimate for each time sample; it also requires initialisation with the environmental constants of the sensor location (x), sensor alignment (u), door width, from hinge to handle, (d) and height of handle (h). These will differ for each sensor so the processing needs to be carried out separately for each sensor. This calculates 5 data models

The suggested processing for the Sensor-Specific Model Generator 16 is:
Background: calculate cos(\hat{θ}) and sin(\hat{θ}), then

$$r ( \hat{θ} ) ≡ [ \begin{matrix}- d cos ( \hat{θ} ) - {x}_{1} \\ - d sin ( \hat{θ} ) - {x}_{2} \\ h - {x}_{3}\end{matrix} ] ,$$

and hence (r(\hat{θ})·u), |r(\hat{θ})|⁻⁵ and |r(\hat{θ})|⁻³
Remanent model: calculate

$${I}_{remanent \_ 1} = \frac{3 ( d - {x}_{1} cos ( \hat{θ} ) + {x}_{2} sin ( \hat{θ} ) ) ( r ( \hat{θ} ) \cdot u )}{{\vert r ( \hat{θ} ) \vert}^{5}} - \frac{( {u}_{1} cos ( \hat{θ} ) - {u}_{2} sin ( \hat{θ} ) )}{{\vert r ( \hat{θ} ) \vert}^{3}} , \\ {I}_{remanent \_ 2} = \frac{3 ( - {x}_{1} sin ( \hat{θ} ) - {x}_{2} cos ( \hat{θ} ) ) ( r ( \hat{θ} ) \cdot u )}{{\vert r ( \hat{θ} ) \vert}^{5}} - \frac{( {u}_{1} sin ( \hat{θ} ) - {u}_{2} cos ( \hat{θ} ) )}{{\vert r ( \hat{θ} ) \vert}^{3}}$$

$$and$$

$${I}_{remanent \_ 3} = \frac{3 ( h - {x}_{3} ) ( r ( \hat{θ} ) \cdot u )}{{\vert r ( \hat{θ} ) \vert}^{5}} - \frac{{u}_{3}}{{\vert r ( \hat{θ} ) \vert}^{3}} .$$

Induced model: calculate

$${I}_{induced \_ 1} ∝ \frac{3 ( - d cos ( \hat{θ} ) - {x}_{1} ) ( r ( \hat{θ} ) \cdot u )}{{\vert r ( \hat{θ} ) \vert}^{5}} - \frac{{u}_{1}}{{\vert r ( \hat{θ} ) \vert}^{3}} and$$

$${I}_{induced \_ 2} ∝ \frac{3 ( d sin ( \hat{θ} ) - {x}_{2} ) ( r ( \hat{θ} ) \cdot u )}{{\vert r ( \hat{θ} ) \vert}^{5}} - \frac{{u}_{2}}{{\vert r ( \hat{θ} ) \vert}^{3}}$$

The Sensor-Specific Model Generator 16 may be changed for specific types of door (e.g. automatic door with door opening piston) which may lead to significantly different data effects. However, as long as this block (and the previous block) are designed to produce real-time data streams out, a like-for-like substitution should be possible with limited difficulty.

The Sensor-Specific Model Generator 16 has the following as inputs:
Environmental Measurements for this sensor (one off):
   x, location of the sensor relative to bottom of door hinge, three numbers (cartesian co-ordinates x₁, x₂ and x₃)
   u, sensor alignment vector, three numbers (the cartesian components of the pointing direction of the sensor)—which form a unit norm vector
   d, door width, same for all sensors
   h, height of handle, same for all sensors
Estimated θ value—one real sample per sample time, from Door Angle Estimator

The Sensor-Specific Model Generator 16 has the following as output:
Modelled Data—five real samples per sample time

Applying the Filter 18 to the Ferroguard sensor outputs and to the model outputs can be simply done in real time. Note that a small delay will be applied to the data by this (but it is less than ¼ of a second and so should not adversely affect Ferroguard alerts). The same filters are to be used for the sensor outputs as for the models.

Note that the filtering of the four modelled signals from the Common Model Generator 14 only needs to be carried out once (and hence the block diagram of FIG. 14 should not be interpreted as implying that the two modelled data streams merge before the Filter 18, since it is more the case that the two modelled data streams merge after the Filter 18). Also note that there is generally no interaction between data streams in the filter, so in effect there will be a set of parallel filters running, one for each sensor signal, five for each model-specific modelled data signal and four for the common modelled data signal.

The Filter 18 has the following as input:
Common Modelled Data—four real samples per sample time, from the Common Model Generator
Sensor-Specific Modelled Data—five real samples for each sensor per sample time, from the Sensor-Specific Model Generator
Sensor Signal—one real sample for each sensor per sample time

The Filter 18 has the following as output:
Filtered versions of the above

Referring now to the Block-Based Coefficient Calculator 20, by using a block-based method here, no continuous algorithm is needed. Instead, the calculations presented above can be used. A suitable number of time samples must be required to form a block—somewhere between 200 and 1000 should be appropriate (1s to 5s minimum).

Note that the Block-Based Coefficient Calculator 20 will be carrying out independent calculations for each sensor signal, but that parts of the calculations of ρₛₑₙₛₒᵣ^{block}=SₛₑₙₛₒᵣX^{H}(XX^{H})⁻¹, (parts of XX^{H} corresponding to eddy-eddy correlation) need to be only calculated once.

The Block-Based Coefficient Calculator 20 has the following as input:
Filtered Modelled Data—nine real samples per sample time, from the Filter 18.

The Block-Based Coefficient Calculator 20 has the following as output:
Block Cancellation Coefficients—nine real values per block time

The main part of the Coefficient Updater 22 should be relatively straightforward to implement. A simple exponential weighted sum should suffice:

ρₛₑₙₛₒᵣ^{current}=(1−λ)ρₛₑₙₛₒᵣ^{current}+λρₛₑₙₛₒᵣ^{block}

where 0.01 is a sensible value of X. It might even be more sensible to use 0.001, as it is believed that ρ is highly stationary.

An additional condition for the Coefficient Updater 22 is that it must cope with switch on—when the first ρ vector is received it must either set this equal to ρ^{current}, or (possibly) average it with a memory stored vector for ρ from when the block was last used.

It is likely (but not certain) that it would be beneficial that the Coefficient Updater 22 receives the value of λ to use from another block (see the description relating to the Adaptation Controller below).

The Coefficient Updater 22 has the following as inputs:
Block Cancellation Coefficients—nine real values per block time, from Block Based Cancellation Coefficient Calculator
Adaptation Coefficient—λ value, may be 0.001 or be an input

The Coefficient Updater 22 has the following as output:
Cancellation Coefficients—nine real values per block time

The Interference Canceller 24 can be a simple real-time block. For each sensor signal it takes in time-stamped values from the filtered sensor output, sₛₑₙₛₒᵣ(t), and from the filtered model data, x(t). It also has a current value of ρ for this sensor from the Coefficient Updater 22, ρₛₑₙₛₒᵣ^{current}. It then carries out:

sₒᵤₜ(t)=sₛₑₙₛₒᵣ(t)−ρₛₑₙₛₒᵣ^{current}x(t)

and returns the cleaned signal output sₒᵤₜ(t).

The Interference Canceller 24 has the following as inputs:
Cancellation Coefficients—nine real values updated once per block time, from Coefficient Updater
Filtered Modelled Data—nine real samples per sample time, from Filter
Filtered Sensor Signal—one real sample per sample time, from Filter

The Interference Canceller 24 has the following as output:
Cleaned Sensor Data—one real value per sample time

While the block diagram of FIG. 14 shows the apparatus related algorithm in their entirety, there are a few other modules that can be beneficial to support the smooth running of the processing. These are mainly to do with setting up the system:
Initial angle estimation model: on set-up the system needs to calculate an interpolation between values for \hat{θ}_{basic}(t)=arctan 2(x(t),y(t)) (x(t) and y(t) being values obtained from the door mounted sensors) and an actual door opening angle. The procedure for doing this has been outlined above. The spline coefficients will need to be stored through a loss of power.
Entering the Environmental Measurements: on set-up the position and orientation of each sensor will need to be entered into the system, along with the height of the door handle and the width of the door. These will need to be stored through a loss of power.
Adaptation Controller: there may need to be a block controlling the rate of adaptation in the coefficient updater. It will likely use as its inputs the door angle estimator, and possibly an input from later on in the signal processing chain where signal detections take place. The output will be a λ value to use in the coefficient updater for that block.

It will be appreciated that, although the above embodiments involve the calculation of the door angle from the door sensor signals, and this door angle is described as being used in subsequent calculations, it is also possible to base the subsequent calculations not on door angle as such, but on some other indicator of door position, such as the (x, y) coordinates of some part of the door. The interference signal canceller can also work directly on the door sensor signals without any such intermediate door position or angle calculation being required. Therefore, it is not essential that there be an intermediate step of calculating the door angle or other such indicator of door position. Likewise, it will be appreciated that the blocks shown in FIGS. 1 and 14 are only schematic, and an implementation may combine any two or more of the illustrative functional blocks together, or alternatively split them apart. It will also be appreciated that the specific model equations set out above are merely examples, and are not to be understood as limiting embodiments of the present invention to use of those particular equations.

It will be appreciated that operation of one or more of the above-described blocks or components can be controlled by a program operating on the device or apparatus. Such an operating program can be stored on a computer-readable medium, or could, for example, be embodied in a signal such as a downloadable data signal provided from an Internet website. The appended claims are to be interpreted as covering an operating program by itself, or as a record on a carrier, or as a signal, or in any other form.

1. An apparatus for compensating for the effect of a moving door on a nearby ferromagnetic object detector, the ferromagnetic object detector being adapted to produce a main sensor signal indicative of the presence of a ferromagnetic object in the vicinity of the ferromagnetic object detector, the door being arranged relative to the ferromagnetic object detector such that movement of the door is liable to introduce an interference signal into the main sensor signal, and the apparatus comprising: an input for receiving the main sensor signal and a door sensor signal that is responsive to an opening angle of the door; interference signal estimator means for estimating a door-related interference signal in dependence upon the door sensor signal and a model of interference for the door; interference signal canceller means for at least partially removing the estimated door-related interference signal from the main sensor signal to produce a compensated sensor signal; and an output for outputting the compensated sensor signal.

2. An apparatus as claimed in claim 1, further comprising door angle estimator means for estimating the door angle using the door sensor signal, and wherein the interference signal estimator means are arranged to estimate the interference signal in dependence upon the estimated door angle.

3. An apparatus as claimed in claim 1, wherein the interference signal estimator means use a model of interference for the door that comprises an element based on eddy currents caused by door shielding.

4. An apparatus as claimed in claim 3, wherein the model is based on a dipole moving with and aligned perpendicular to the door.

5. An apparatus as claimed in claim 1, wherein the interference signal estimator means use a model of interference for the door that that comprises an element based on remanent and/or induced magnetic effects from a handle or other metal object moving with the door.

6. An apparatus as claimed in claim 5, wherein the model is based on a dipole moving with the door, for example at or near the handle or other metal object, in substantially fixed alignment relative to the door in the case of remanent magnetism and in substantially fixed alignment relative to a background magnetic field in the case of induced magnetism.

7. An apparatus as claimed in claim 5, further comprising door angle estimator means for estimating the door angle using the door sensor signal, and wherein the interference signal estimator means are arranged to estimate the interference signal in dependence upon the estimated door angle, wherein the interference signal estimator means are arranged to estimate the interference signal based on at least one of the following functions:
$${I}_{remanent \_ 1} ∝ \frac{3 ( d - {x}_{1} cos ( \hat{θ} ) + {x}_{2} sin ( \hat{θ} ) ) ( r ( \hat{θ} ) \cdot u )}{{\vert r ( \hat{θ} ) \vert}^{5}} - \frac{( {u}_{1} cos ( \hat{θ} ) - {u}_{2} sin ( \hat{θ} ) )}{{\vert r ( \hat{θ} ) \vert}^{3}} ;$$
$${I}_{remanent \_ 2} ∝ \frac{3 ( - {x}_{1} sin ( \hat{θ} ) - {x}_{2} cos ( \hat{θ} ) ) ( r ( \hat{θ} ) \cdot u )}{{\vert r ( \hat{θ} ) \vert}^{5}} - \frac{( {u}_{1} sin ( \hat{θ} ) - {u}_{2} cos ( \hat{θ} ) )}{{\vert r ( \hat{θ} ) \vert}^{3}} ; and$$
$${I}_{remanent \_ 3} ∝ \frac{3 ( h - {x}_{3} ) ( r ( \hat{θ} ) \cdot u )}{{\vert r ( \hat{θ} ) \vert}^{5}} - \frac{{u}_{3}}{{\vert r ( \hat{θ} ) \vert}^{3}} ;$$
where \hat{θ} represents the door angle, where x₁,x₂,x₃ represent Cartesian coordinates of the position of a sensor of the ferromagnetic object detector relative to a hinge of the door, where r(\hat{θ}) represents a vector from the sensor to the handle or other metal object, where u represents a sensor alignment vector, where d represents a distance between the hinge of the door and the handle or other metal object, and where h represents a height difference between the sensor and the handle or other metal object.

8. An apparatus as claimed in claim 5, further comprising door angle estimator means for estimating the door angle using the door sensor signal, and wherein the interference signal estimator means are arranged to estimate the interference signal in dependence upon the estimated door angle, wherein the interference signal estimator means are arranged to estimate the interference signal based on at least one of the following functions:
$${I}_{induced \_ 1} ∝ \frac{3 ( - d cos ( \hat{θ} ) - {x}_{1} ) ( r ( \hat{θ} ) \cdot u )}{{\vert r ( \hat{θ} ) \vert}^{5}} - \frac{{u}_{1}}{{\vert r ( \hat{θ} ) \vert}^{3}} ;$$
$${I}_{induced \_ 2} ∝ \frac{3 ( d sin ( \hat{θ} ) - {x}_{2} ) ( r ( \hat{θ} ) \cdot u )}{{\vert r ( \hat{θ} ) \vert}^{5}} - \frac{{u}_{2}}{{\vert r ( \hat{θ} ) \vert}^{3}} ; and$$
$${I}_{induced \_ 3} ∝ \frac{3 ( h - {x}_{3} ) ( r ( \hat{θ} ) \cdot u )}{{\vert r ( \hat{θ} ) \vert}^{5}} - \frac{{u}_{3}}{{\vert r ( \hat{θ} ) \vert}^{3}} = {I}_{remanent \_ 3} ;$$
where \hat{θ} represents the door angle, where x₁,x₂,x₃ represent Cartesian coordinates of the position of a sensor of the ferromagnetic object detector relative to a hinge of the door, where r(\hat{θ}) represents a vector from the sensor to the handle or other metal object, where u represents a sensor alignment vector, where d represents a distance between the hinge of the door and the handle or other metal object, and where h represents a height difference between the sensor and the handle or other metal object.

9. An apparatus as claimed in claim 1, wherein the received door sensor signal comprises two signals x(t) and y(t), representing magnetic field strength in two different respective directions.

10. An apparatus as claimed in claim 9, further comprising door angle estimator means for estimating the door angle using the door sensor signal, and wherein the interference signal estimator means are arranged to estimate the interference signal in dependence upon the estimated door angle wherein the door angle estimator means are arranged to estimate the door angle \hat{θ}(t) as a function of arctan 2(x(t), y(t)), where arctan 2 denotes a 4-quadrent arctangent function.

11. An apparatus as claimed in claim 9 further comprising door angle estimator means for estimating the door angle using the door sensor signal, and wherein the interference signal estimator means are arranged to estimate the interference signal in dependence upon the estimated door angle, wherein the interference signal estimator means use a model of interference for the door that comprises an element based on eddy currents caused by door shielding and wherein the interference signal estimator means are arranged to estimate the interference signal based on at least one of the following functions:
$${I}_{eddy \_ 1} ∝ cos ( \hat{θ} ) \frac{\partial }{\partial t} ( y ( t ) ) ;$$
$${I}_{eddy \_ 2} ∝ sin ( \hat{θ} ) \frac{\partial }{\partial t} ( y ( t ) ) ;$$
$${I}_{eddy \_ 3} ∝ {cos}^{2} ( \hat{θ} ) \frac{\partial }{\partial t} ( y ( t ) ) ;$$
$${I}_{eddy \_ 4} ∝ {sin}^{2} ( \hat{θ} ) \frac{\partial }{\partial t} ( y ( t ) ) ; and$$
$${I}_{eddy \_ 5} ∝ sin ( \hat{θ} ) cos ( \hat{θ} ) \frac{\partial }{\partial t} ( y ( t ) ) ;$$
where \hat{θ}(t) represents the estimated door angle.

12. An apparatus as claimed in claim 9, wherein the door sensor comprises two flux-gate sensors arranged respectively to produce the two signals x(t) and y(t).

13. An apparatus as claimed in claim 12, wherein the flux-gate sensors are arranged with substantially orthogonal headings.

14. An apparatus as claimed in claim 13, wherein one of the flux-gate sensors is arranged substantially parallel to the door and to the ground, while the other is arranged substantially parallel to the ground and orthogonal to the door.

15. An apparatus as claimed in claim 1, wherein the interference signal canceller means are arranged to use a block-based method of at least partially removing the estimated door-related interference signal from the main sensor signal, for example an adaptive cancellation method.

16. An apparatus as claimed in claim 15, wherein the interference signal canceller means are arranged to determine the compensated sensor signal S′ according to S′=S−ρX where S is a data vector and X is a data matrix, containing the main signal and modelled interference signals respectively, and where is a vector of cancellation coefficients calculated according to ρ=SX^{H}(XX^{H})⁻¹.

17. A system comprising a ferromagnetic object detector and an apparatus as claimed in claim 1.

18. A magnetic resonance imaging scanner comprising a system as claimed in claim 17.

19. A method for compensating for the effect of a moving door on a nearby ferromagnetic object detector, the ferromagnetic object detector being adapted to produce a main sensor signal indicative of the presence of a ferromagnetic object in the vicinity of the ferromagnetic object detector, the door being arranged relative to the ferromagnetic object detector such that movement of the door is liable to introduce an interference signal into the main sensor signal, and the method comprising: receiving the main sensor signal and a door sensor signal that is responsive to an opening angle of the door; estimating a door-related interference signal in dependence upon the door sensor signal and a model of interference for the door; at least partially removing the estimated door-related interference signal from the main sensor signal to produce a compensated sensor signal; and outputting the compensated sensor signal.

20. A non-transient carrier medium bearing a program for controlling an apparatus to perform a method as claimed in claim 19.

21-24. (canceled)
